(19) United States
(12) Patent Application Publication
(10) Pub. No.: US 2024/0234634 A1
(43) Pub. Date: Jul. 11, 2024

(54) DISPLAY DEVICE AND METHOD OF MANUFACTURING DISPLAY DEVICE

(71) Applicant: Samsung Display Co., LTD., Yongin-si (KR)

(72) Inventors: Jin Woo CHOI, Yongin-si (KR); Dae Ho SONG, Yongin-si (KR); Hyung Il JEON, Yongin-si (KR)

(21) Appl. No.: 18/396,464

(22) Filed: Dec. 26, 2023

(30) Foreign Application Priority Data
Jan. 6, 2023 (KR) 10-2023-0002464

(51) Int. Cl. H01L 33/38; H01L 25/16; H01L 33/10

(52) U.S. Cl. CPC H01L 33/38; H01L 25/167; H01L 33/10; H01L 2933/0016

(57) ABSTRACT

A display device and a method of manufacturing the same. The display device includes: a pixel circuit layer and a light emitting element on the pixel circuit layer. The light emitting element includes first and second electrodes and an emission layer electrically connected to the first electrode through a first contact portion and electrically connected to the second electrode through a second contact portion. The emission layer includes: a first sub-emission layer including a first N-type semiconductor layer, a first P-type semiconductor layer, and a first active layer between the first N-type semiconductor layer and the first P-type semiconductor layer; and a second sub-emission layer including a second N-type semiconductor layer, a second P-type semiconductor layer, and a second active layer between the second N-type semiconductor layer and the second P-type semiconductor layer. The first and second sub-emission layers are electrically connected in series between the first and second electrodes.

### CROSS-REFERENCED TO RELATED APPLICATION

This application claims priority to and the benefit Korean Patent Application No. 10-2023-0002464, filed on Jan. 6, 2023, in the Korean Intellectual Property Office, the entire content of which is incorporated herein by reference.

### BACKGROUND

### 1. Field

Aspects of embodiments of the present disclosure relate to a display device and a method of manufacturing the display device.

### 2. Description of the Related Art

Recently, as interest in information displays has increased, research and development into display devices is being continuously conducted.

### SUMMARY

Embodiments of the present disclosure provide a display device that can prevent malfunction of a light emitting element and a method of manufacturing the same.

According to an embodiment of the present disclosure, a display device includes: a pixel circuit layer including a base layer and a pixel circuit on the base layer; and a light emitting element on the pixel circuit layer. The light emitting element includes a first electrode, a second electrode, and an emission layer electrically connected to the first electrode through a first contact portion and electrically connected to the second electrode through a second contact portion. The emission layer includes a first sub-emission layer including a first N-type semiconductor layer, a first P-type semiconductor layer, and a first active layer between the first N-type semiconductor layer and the first P-type semiconductor layer and a second sub-emission layer including a second N-type semiconductor layer, a second P-type semiconductor layer, and a second active layer between the second N-type semiconductor layer and the second P-type semiconductor layer. The first sub-emission layer and the second sub-emission layer are electrically connected in series between the first electrode and the second electrode.

According to an embodiment, the pixel circuit layer may include a first power source and a second power source. The first power source may be electrically connected to the pixel circuit layer. The first sub-emission layer and the second sub-emission layer may be electrically connected between the pixel circuit layer and the second power source.

According to an embodiment, the emission layer may further include a distributed Bragg reflective layer on the second P-type semiconductor layer. The first sub-emission layer may further include a first superlattice layer between the first N-type semiconductor layer and the first active layer and a first electron blocking layer between the first active layer and the first P-type semiconductor layer. The second sub-emission layer may further include a second superlattice layer between the second N-type semiconductor layer and the second active layer and a second electron blocking layer between the second active layer and the second P-type semiconductor layer.

According to an embodiment, the emission layer may further include an electrode layer between the first P-type semiconductor layer and the second N-type semiconductor layer.

According to an embodiment, the first P-type semiconductor layer and the second N-type semiconductor layer may contact each other.

According to an embodiment, the display device may further include a quantum-dot layer on the emission layer. Light emitted by the emission layer may pass through the quantum-dot layer.

According to an embodiment, the display device may further include a first sub-pixel area from which light of a first color is emitted, a second sub-pixel area from which light of a second color is emitted, and a third sub-pixel area from which light of a third color is emitted. The emission layer may include a first emission layer overlapping the first sub-pixel area, a second emission layer overlapping the second sub-pixel area, and a third emission layer overlapping the third sub-pixel area in a plan view.

According to an embodiment, the first sub-emission layer and the second sub-emission layer may form a light emitting unit. The light emitting unit may include a first light emitting unit and a second light emitting unit. The first light emitting unit and the second light emitting unit may be in each of the first sub-pixel area, the second sub-pixel area, and the third sub-pixel area.

According to an embodiment, the second electrode may include a (2-1)th electrode corresponding to the first light emitting unit and a (2-2)th electrode corresponding to the second light emitting unit.

According to an embodiment, the pixel circuit layer may include a first power source and a second power source. The first light emitting unit and the second light emitting unit may be electrically connected in parallel between the first power source and the second power source.

According to an embodiment, the second contact portion may include a plurality of contact portions in each of the first sub-pixel area, the second sub-pixel area, and the third sub-pixel area.

According to an embodiment of the present disclosure, a display device includes sub-pixels. The display device includes a pixel circuit layer including a base layer and a pixel circuit on the base layer, and a light emitting element on the pixel circuit layer. The light emitting element includes a first electrode, a second electrode, an emission layer electrically connected to the first electrode through a first contact portion and electrically connected to the second electrode through a second contact portion, and a quantum-dot layer on the emission layer. Each of the sub-pixels has a sub-pixel area overlapping the quantum-dot layer in a plan view. The second contact portion may include contact portions in the sub-pixel area of each of the sub-pixels.

According to an embodiment of the present disclosure, a method of manufacturing a display device includes manufacturing a light emitting element and transferring the light emitting element onto a pixel circuit layer. Manufacturing the light emitting element includes manufacturing a first sub-emission layer including a first N-type semiconductor layer, a first P-type semiconductor layer, and a first active layer between the first N-type semiconductor layer and the first P-type semiconductor layer, manufacturing a second sub-emission layer including a second N-type semiconductor layer, a second P-type semiconductor layer, and a second active layer between the second N-type semiconductor layer and the second P-type semiconductor layer, and forming a first electrode electrically connected to the first N-type semiconductor layer at a first contact portion and a second electrode electrically connected to the second P-type semiconductor layer at a second contact portion. The first sub-emission layer and the second sub-emission layer are electrically connected in series between the first electrode and the second electrode.

According to an embodiment, the manufacturing of the light emitting element may include further forming a first electrode layer on the first sub-emission layer, forming a second electrode layer on the second sub-emission layer, and bonding the first electrode layer and the second electrode layer.

According to an embodiment, the first sub-emission layer and the second sub-emission layer may be sequentially formed on a growth substrate.

According to an embodiment, the manufacturing of the first sub-emission layer may include forming an undoped semiconductor layer on a growth substrate. The method may further include forming a porous structure by performing an electrochemical etching process on the undoped semiconductor layer, and forming a quantum-dot layer by performing an inkjet printing process of providing an ink including a quantum-dot to the porous structure.

According to an embodiment, the method may further include forming a passivation layer covering the quantum-dot layer and the emission layer.

According to an embodiment, the display device may include a plurality of sub-pixels. The second electrode may include a (2-1)th electrode and a (2-2)th electrode. The (2-1)th electrode and the (2-2)th electrode may be in each of the plurality of sub-pixels.

According to an embodiment, the manufacturing of the first sub-emission layer may include forming a superlattice layer between the first N-type semiconductor layer and the first active layer and forming an electron blocking layer between the first active layer and the first P-type semiconductor layer.

According to an embodiment of the present disclosure, a method of manufacturing a display device includes manufacturing a light emitting element and transferring the light emitting element onto a pixel circuit layer. The manufacturing of the light emitting element includes manufacturing an emission layer, forming a first electrode electrically connected to a first contact portion of the emission layer and a second electrode electrically connected to a second contact portion of the emission layer, and forming a quantum-dot layer on the emission layer. The manufacturing of the emission layer includes disposing an undoped semiconductor layer, an N-type semiconductor layer, an active layer, and a P-type semiconductor layer on a growth substrate. The emission layer forms a first light emitting unit and a second light emitting unit. The forming of the second electrode includes forming a (2-1)th electrode corresponding to the first light emitting unit and a (2-2)th electrode corresponding to the second light emitting unit.

According to embodiments of the present disclosure, a display device that prevents malfunction of a light emitting element a method of manufacturing the display device may be provided.

### BRIEF DESCRIPTION OF THE DRAWINGS

The above and other aspects and features of the present disclosure will become more apparent by describing, in detail, embodiments thereof with reference to the accompanying drawings, in which:

FIG. 1 is a plan view illustrating a display device according to an embodiment;

FIG. 2 is a schematic diagram illustrating an example of a pixel shown in FIG. 1;

FIG. 3 is a schematic cross-sectional view illustrating a light emitting element according to an embodiment;

FIGS. 4 to 7, 9, and 10 are schematic cross-sectional views illustrating a light emitting element according to various embodiments;

FIG. 8 is a schematic diagram illustrating a series connection structure of emission layers according to an embodiment;

FIGS. 11 and 13 are schematic plan views illustrating a display device according to various embodiments;

FIG. 12 is a schematic cross-sectional view taken along the line A-A′ of FIG. 11;

FIG. 14 is a schematic diagram illustrating a parallel connection structure of emission layers according to an embodiment;

FIG. 15 is a flowchart describing a method of manufacturing a display device according to an embodiment; and

FIGS. 16 to 25 are schematic cross-sectional views of process phases of a method of manufacturing a display device according to an embodiment.

### DETAILED DESCRIPTION

The present disclosure may be modified in various manners and may have various forms. Therefore, while embodiments will be illustrated in the drawings and will be described, in detail, in the specification, it should be understood that the present disclosure is not intended to be limited to the described embodiments. Rather, the present disclosure includes all modifications, equivalents, and substitutions within the spirit and technical scope of the present disclosure.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Hereinafter, a display device and a method of manufacturing the display device according to embodiments of the present disclosure are described with reference to the accompanying drawings.

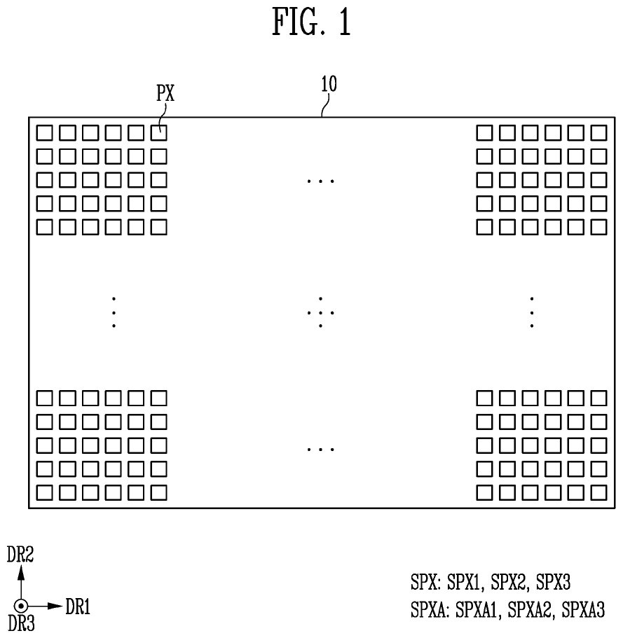

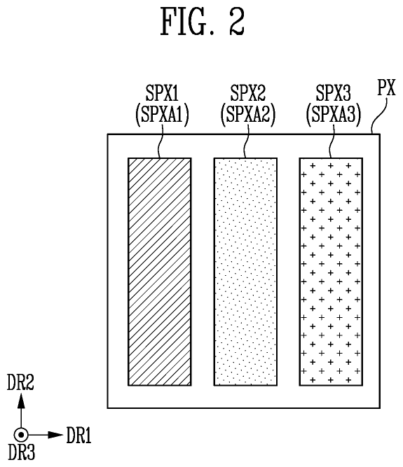

First, referring to FIGS. 1 to 3, a display device 10 according to an embodiment is described. FIG. 1 is a plan view illustrating the display device 10, and FIG. 2 is a diagram illustrating an example of a pixel of the display device 10 shown in FIG. 1.

Referring to FIG. 1, the display device 10 is configured to output light information (e.g., to output light to display an image). For example, the display device 10 may be a device for displaying a moving image and/or a still image, and the display device 10 may be applied to various devices. The display device 10 may have a rectangular planar shape having a long side in a first direction DR1 and a short side in a second direction DR2 crossing (or intersecting) the first direction DR1. A corner at where the long side and the short side meet may be rounded to have a curvature (e.g., a predetermined curvature) or may form a right angle. A planar shape of the display device 10 is not limited to a quadrangle and may have the shape of another polygon, circle, or ellipse. The display device 10 may be flat but is not limited thereto. For example, the display device 10 may have a curved portion formed at left and right ends and may have a constant curvature or a varying curvature. In addition, the display device 10 may be flexibly formed to be crooked, curved, bent, folded, or rolled.

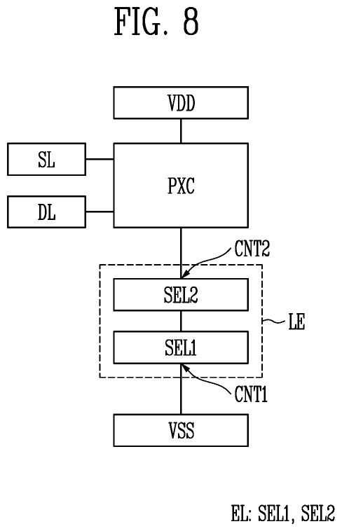

The display device 10 may further include pixels PX, scan lines SL (see, e.g., FIG. 8) extending in the first direction DR1, and data lines DL (see, e.g., FIG. 8) extending in the second direction DR2 to display an image. The pixels PX may be arranged in a matrix in the first direction DR1 and the second direction DR2.

Each of the pixels PX may include sub-pixels SPX1, SPX2, and SPX3, as shown in FIG. 2. The respective sub-pixels SPX1, SPX2, and SPX3 may have (or may form) sub-pixel areas SPXA1, SPXA2, and SPXA3 from which light of one color is emitted.

FIG. 2 illustrates an embodiment in which each of the pixels PX includes three sub-pixels SPX1, SPX2 and SPX3, that is, a first sub-pixel SPX1, a second sub-pixel SPX2, and a third sub-pixel SPX3, but the present disclosure is not limited thereto.

The first sub-pixel SPX1, the second sub-pixel SPX2, and the third sub-pixel SPX3 may be connected to (e.g., may each be connected to) any one data line DL from among the data lines DL and at least one scan line SL from among the scan lines SL.

Each of the first sub-pixel SPX1, the second sub-pixel SPX2, and the third sub-pixel SPX3 may have a planar shape of a rectangle, a square, or a rhombus. For example, as shown in FIG. 2, each of the first sub-pixel SPX1, the second sub-pixel SPX2, and the third sub-pixel SPX3 may have a planar shape of a rectangle having a short side in the first direction DR1 and a long side in the second direction DR2. In another embodiment, each of the first sub-pixel SPX1, the second sub-pixel SPX2, and the third sub-pixel SPX3 may have a square or a rhombus planar shape with sides having the same length in the first direction DR1 and the second direction DR2.

As shown in FIG. 2, the first sub-pixel SPX1, the second sub-pixel SPX2, and the third sub-pixel SPX3 may be arranged in the first direction DR1. In another embodiment, one of the second sub-pixel SPX2 and the third sub-pixel SPX3 may be arranged in the first direction DR1 with the first sub-pixel SPX1, and the other one of the second sub-pixel SPX2 and the third sub-pixel SPX3 may be arranged in the second direction DR2 with the first sub-pixel SPX1.

In another embodiment, any one of the first sub-pixel SPX1 and the third sub-pixel SPX3 may be arranged in the first direction DR1 with the second sub-pixel SPX2, and the other one of the first sub-pixel SPX1 and the third sub-pixel SPX3 may be arranged in the second direction DR2 with the second sub-pixel SPX2. In another embodiment, any one of the first sub-pixel SPX1 and the second sub-pixel SPX2 may be arranged in the first direction DR1 with the third sub-pixel SPX3, and the other one of the first sub-pixel SPX1 and the second sub-pixel SPX2 may be arranged in the second direction DR2 with the third sub-pixel SPX3.

The first sub-pixel SPX1 may emit first light, the second sub-pixel SPX2 may emit second light, and the third sub-pixel SPX3 may emit third light. In one embodiment, the first light may be light of a red wavelength band, the second light may be light of a green wavelength band, and the third light may be light of a blue wavelength band. The red wavelength band may be a wavelength band in a range of about 600 nm to about 750 nm, the green wavelength band may be a wavelength band in a range of about 480 nm to about 560 nm, and the blue wavelength band may be a wavelength band in a range of about 370 nm to about 460 nm, but the present disclosure is not limited thereto.

According to an embodiment, a first sub-pixel SPX1 may form a first sub-pixel area SPXA1 from which light of a first color is emitted. A second sub-pixel SPX2 may form a second sub-pixel area SPXA2 from which light of a second color is emitted. A third sub-pixel SPX3 may form a third sub-pixel area SPXA3 from which light of a third color is emitted.

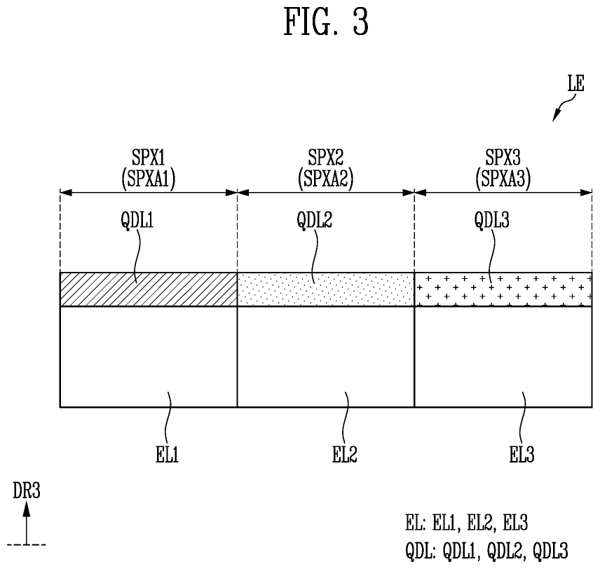

Each of the first sub-pixel SPX1, the second sub-pixel SPX2, and the third sub-pixel SPX3 may include an inorganic light emitting element including an inorganic semiconductor as a light emitting element LE (see, e.g., FIG. 3) that is configured to emit light.

As shown in FIG. 2, the area of the first sub-pixel SPX1, the area of the second sub-pixel SPX2, and the area of the third sub-pixel SPX3 may be substantially the same, but the present specification is not limited thereto. At least one of the area of the first sub-pixel SPX1, the area of the second sub-pixel SPX2, and the area of the third sub-pixel SPX3 may be different from another area. In some embodiments, any two of the area of the first sub-pixel SPX1, the area of the second sub-pixel SPX2, and the area of the third sub-pixel SPX3 may be substantially the same and the other one may be different from the two areas. In some embodiments, the area of the first sub-pixel SPX1, the area of the second sub-pixel SPX2, and the area of the third sub-pixel SPX3 may be different from each other.

Hereinafter, with reference to FIGS. 3 to 14, the light emitting elements LE and the display device 10 including the light emitting elements LE according to an embodiment are described.

FIG. 3 is a schematic cross-sectional view illustrating a light emitting element according to an embodiment.

Referring to FIG. 3, the light emitting element LE may include an emission layer EL and a quantum-dot layer QDL. According to an embodiment, light provided by (or emitted from) the emission layer EL may be emitted through (or may pass through) the quantum-dot layer QDL. According to an embodiment, the light emitting element LE may have a flip-chip light emitting structure in which the emission layer EL and the quantum-dot layer QDL are integrated.

The emission layer EL may include emission layers EL1, EL2, and EL3 corresponding to the respective sub-pixels SPX1, SPX2, and SPX3. For example, the emission layer EL may include a first emission layer EL1, a second emission layer EL2, and a third emission layer EL3. The first emission layer EL1 may overlap the first sub-pixel area SPXA1 in a plan view. The second emission layer EL2 may overlap the second sub-pixel area SPXA2 in a plan view. The third emission layer EL3 may overlap the third sub-pixel area SPXA3 in a plan view.

According to an embodiment, the first to third emission layers EL1, EL2, and EL3 may emit the same light as each other. For example, the first to third emission layers EL1, EL2, and EL3 may emit light of a third color. The light of the same color may pass through different quantum-dot layers QDL so that light of a first color may be provided in (or may be emitted from) the first sub-pixel area SPXA1, light of a second color may be provided in the second sub-pixel area SPXA2, and light of a third color may be provided in the third sub-pixel area SPXA3. Accordingly, the light emitting element LE may form a pixel unit configured to provide (or emit) two or more colors of light.

However, the present disclosure is not limited thereto. According to an embodiment, the first to third emission layers EL1, EL2, and EL3 may emit light of different colors. For example, the first emission layer EL1 may emit light of the first color, the second emission layer EL2 may emit light of the second color, and the third emission layer EL3 may emit light of the third color. Hereinafter, for convenience of description, an embodiment in which the first to third emission layers EL1, EL2, and EL3 emit light of the same color is described.

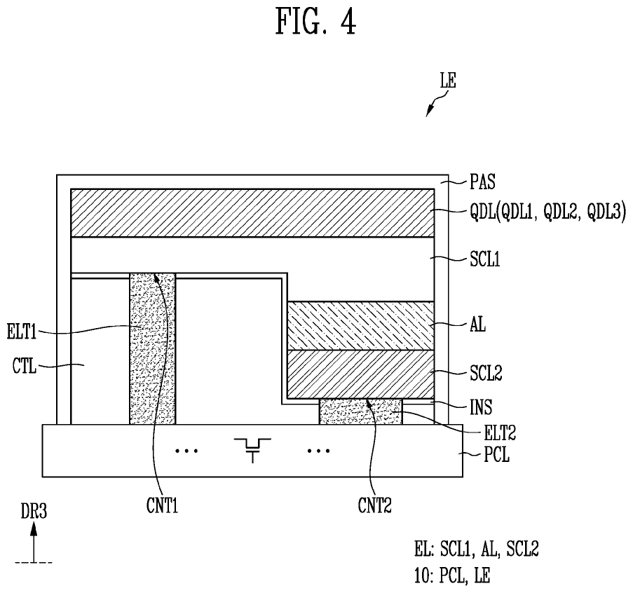

Hereinafter, the light emitting element LE according to an embodiment is described with reference to FIGS. 4 to 10.

FIGS. 4 to 7, 9, and 10 are schematic cross-sectional views illustrating a light emitting element according to various embodiments. For example, FIGS. 4 to 7, 9, and 10 show a cross-sectional structure of the light emitting element LE in one sub-pixel area SPXA and show a structure in which the light emitting element LE is disposed on a schematically illustrated pixel circuit layer PCL.

In the drawings below, the emission layer EL may be one of the first to third emission layers EL1, EL2, and EL3, and the quantum-dot layer QDL may be one of first to third quantum dot layers QDL1, QDL2, and QDL3. FIG. 8 is a schematic diagram illustrating a series connection structure of emission layers according to an embodiment.

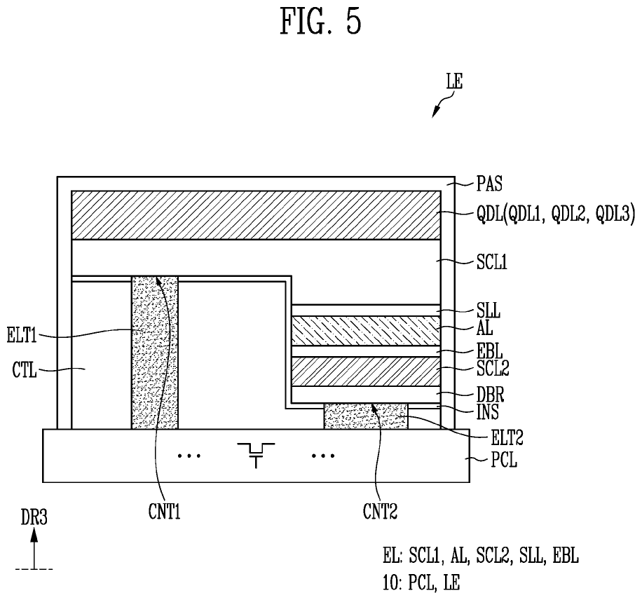

First, referring to FIGS. 4 and 5, a light emitting element LE according to a first embodiment is described. FIGS. 4 and 5 are schematic cross-sectional views illustrating the light emitting element according to the first embodiment.

Referring to FIGS. 4 and 5, the display device 10 may include the pixel circuit layer PCL and the light emitting element LE disposed on the pixel circuit layer PCL.

The pixel circuit layer PCL may be a layer including a pixel circuit PXC (see, e.g., FIG. 8) for driving the light emitting elements LE. The pixel circuit layer PCL may include a base layer, metal layers for forming the pixel circuits PXC, and insulating layers disposed between the metal layers.

According to an embodiment, the base layer may be a base substrate or a base member for supporting the display device 10. The base substrate may be a rigid substrate of a glass material, and the base layer may be a flexible substrate which can be bent, folded, rolled, or the like. The base member may include an insulating material, such as a polymer resin, for example, polyimide.

According to an embodiment, the pixel circuits PXC may include a thin film transistor. The pixel circuits PXC may further include a storage capacitor.

The pixel circuits PXC may be electrically connected to the light emitting elements LE to provide an electrical signal for the light emitting elements LE to emit light. For example, the pixel circuit layer PCL may include a first line electrically connected to a first electrode ELT1 to supply a cathode signal and a second line electrically connected to a second electrode ELT2 to supply an anode signal.

According to an embodiment, the pixel circuit layer PCL may include a protective layer (e.g., a via layer) adjacent to the light emitting element LE. According to an embodiment, the protective layer may be an organic via layer. According to an embodiment, the first line of the pixel circuit layer PCL may be electrically connected to the first electrode ELT1 through a first contact member passing through the protective layer, and the second line of the pixel circuit layer PCL may be electrically connected to the second electrode ELT2 through a second contact member passing through the protective layer.

The light emitting element LE may include the first electrode ELT1, the second electrode ELT2, the emission layer EL, and the quantum-dot layer QDL. The light emitting element LE may further include an intermediate layer CTL, an insulating layer INS, and a passivation layer PAS.

The first electrode ELT1 may be disposed on the pixel circuit layer PCL. According to an embodiment, at least a portion of the first electrode ELT1 may pass through the intermediate layer CTL. The first electrode ELT1 may be electrically connected to the first line of the pixel circuit layer PCL. The first electrode ELT1 may be electrically connected to the emission layer EL at a first contact portion CNT1 of the emission layer EL. The first electrode ELT1 may receive the cathode signal for the emission layer EL to emit light.

The second electrode ELT2 may be disposed on the pixel circuit layer PCL. According to an embodiment, at least a portion of the second electrode ELT2 may pass through the intermediate layer CTL. The second electrode ELT2 may be electrically connected to the second line of the pixel circuit layer PCL. The second electrode ELT2 may be electrically connected to the emission layer EL at a second contact portion CNT2 of the emission layer EL. The second electrode ELT2 may receive the anode signal for the emission layer EL to emit light. For example, the second electrode ELT2 may be electrically connected to the pixel circuit PXC (e.g., a driving transistor).

The first electrode ELT1 and the second electrode ELT2 may include a conductive material. For example, the first electrode ELT1 and the second electrode ELT2 may include one or more of a group of gold (Au), silver (Ag), aluminum (Al), molybdenum (Mo), chromium (Cr), titanium (Ti), nickel (Ni), neodymium (Nd), copper (Cu), and platinum (Pt). However, the present disclosure is not limited to the above example. According to an embodiment, the first electrode ELT1 and the second electrode ELT2 may include a transparent conductive oxide.

According to an embodiment, the first electrode ELT1 may overlap an N-type semiconductor layer SCL1 in a plan view. The second electrode ELT2 may overlap the N-type semiconductor layer SCL1, an active layer AL, and a P-type semiconductor layer SCL2 in a plan view. According to an embodiment, the first electrode ELT1 may not overlap (e.g., may be offset from) the active layer AL and the P-type semiconductor layer SCL2 in a plan view.

The emission layer EL may be electrically connected between the first electrode ELT1 and the second electrode ELT2. For example, the first contact portion CNT1 of the emission layer EL may be electrically connected to the first electrode ELT1, and the second contact portion CNT2 of the emission layer EL may be electrically connected to the second electrode ELT2.

The emission layer EL is configured to emit light. The light emitting element LE may include the N-type semiconductor layer SCL1, the P-type semiconductor layer SCL2, and the active layer AL disposed between the N-type semiconductor layer SCL1 and the P-type semiconductor layer SCL2.

The N-type semiconductor layer SCL1 may be disposed on the active layer AL. The N-type semiconductor layer SCL1 may include an N-type semiconductor. For example, the N-type semiconductor layer SCL1 may include one or more selected from a group of InAlGaN, GaN, AlGaN, InGaN, AlN, and InN, and may be doped with a first conductivity type dopant, such as Si, Ge, and Sn. However, the present disclosure is not limited to the above-described example.

The active layer AL may be disposed between the N-type semiconductor layer SCL1 and the P-type semiconductor layer SCL2. The active layer AL may have a single-quantum well or multi-quantum well structure. A position of the active layer AL is not limited and may be variously changed according to a type of the light emitting element LE.

The P-type semiconductor layer SCL2 may be disposed on the active layer AL. The P-type semiconductor layer SCL2 may include a P-type semiconductor. For example, the P-type semiconductor layer SCL2 may include one or more semiconductor materials selected from a group of InAlGaN, GaN, AlGaN, InGaN, AlN, and InN, and may be doped with a second conductivity type dopant, such as Ga, B, and Mg. However, the present disclosure is not limited to the above-described example.

When a voltage equal to or higher than a threshold voltage is applied to the first contact portion CNT1 and the second contact portion CNT2 of the light emitting element LE, an electron-hole pair may recombine with each other in the active layer AL, and the light emitting element LE may emit light. By controlling emission of the light emitting element LE using such a principle, the light emitting element LE may be used as a light source in various devices.

The quantum-dot layer QDL may be disposed on the emission layer EL. The quantum-dot layer QDL may be disposed on the N-type semiconductor layer SCL1. According to an embodiment, the quantum-dot layer QDL may contact the N-type semiconductor layer SCL1. The quantum-dot layer QDL may be directly disposed on the N-type semiconductor layer SCL1. For example, the quantum-dot layer QDL may be subsequently formed after the emission layer EL is manufactured and may be packaged together with the emission layer EL.

The quantum-dot layer QDL may be disposed outside the emission layer EL based on a display direction (e.g., a third direction DR3) of the display device 10. The quantum-dot layer QDL may convert applied (or incident) light into light of one color.

For example, the first quantum-dot layer QDL1 may include first color conversion particles that convert the light of the first color in the first sub-pixel area SPXA1. For example, the first quantum-dot layer QDL1 may include a plurality of first quantum dots dispersed in a matrix material, such as a base resin. According to an embodiment, the first quantum dot may emit the light of the first color by absorbing the light of the third color and shifting a wavelength according to an energy transition.

For example, the second quantum-dot layer QDL2 may include second color conversion particles that convert the light of the second color in the second sub-pixel area SPXA2. For example, the second quantum-dot layer QDL2 may include a plurality of second quantum dots dispersed in a matrix material, such as a base resin. According to an embodiment, the second quantum dot may emit the light of the second color by absorbing the light of the third color and shifting a wavelength according to an energy transition.

According to an embodiment, the third quantum-dot layer QDL3 may include scatterers to improve light efficiency in the third sub-pixel area SPXA3. According to an embodiment, the scatterers may include one or more of silica (SiOₓ) (e.g., a silica bead, hollow silica, or the like), titanium oxide (TiOₓ), zirconium oxide (ZrOₓ), aluminum oxide (AlₓO_{y}), indium oxide (InₓO_{y}), zinc oxide (ZnOₓ), tin oxide (SnOₓ), and antimony oxide (SbₓO_{y}). However, the present disclosure is not limited thereto. According to an embodiment, the third quantum-dot layer QDL3 may include a color conversion particle configured to convert light of one color into the light of the third color.

According to an embodiment, the emission layer EL and the quantum-dot layer QDL may form one unit. For example, when manufacturing the light emitting elements LE, the quantum-dot layer QDL may be subsequently formed after the emission layer EL is manufactured, and the emission layer EL and the quantum-dot layer QDL may be covered by the passivation layer PAS to form a chip. In such an embodiment, when the light emitting elements LE are transferred to the pixel circuit layer PCL after manufacturing the light emitting elements LE, the light emitting layer EL and the quantum-dot layer QDL may be disposed on the pixel circuit layer PCL at the same time, even if an additional process is not performed to manufacture a layer including a quantum-dot structure. Accordingly, process convenience can be improved, and because the quantum-dot layer QDL is disposed adjacent to the emission layer EL, color reproducibility is improved.

According to an embodiment, the intermediate layer CTL may be disposed between the pixel circuit layer PCL, the first electrode ELT1, the second electrode ELT2, and the emission layers EL. According to an embodiment, the intermediate layer CTL may be a transparent viscosity layer (or adhesive layer) but is not limited thereto, and the intermediate layer CTL may include an organic material.

According to an embodiment, the insulating layer INS may be disposed on the emission layer EL. For example, the insulating layer INS may be disposed between the emission layer EL and the intermediate layer CTL. According to an embodiment, the insulating layer INS may protect the emission layer EL and may include an inorganic material. For example, the insulating layer INS may include one or more of silicon nitride (SiNₓ), silicon oxide (SiOₓ), silicon oxynitride (SiOₓN_{y}), and aluminum oxide (AlOₓ). However, the present disclosure is not limited to the above-described example.

According to an embodiment, the passivation layer PAS may be disposed on the quantum-dot layer QDL and the emission layer EL to cover the quantum-dot layer QDL and the emission layer EL. The passivation layer PAS may package (e.g., seal) the quantum-dot layer QDL and the emission layer EL. The passivation layer PAS may cover both the quantum-dot layer QDL and the emission layer EL. The passivation layer PAS may cover the emission layer EL and the quantum-dot layer QDL for each pixel PX. For example, the passivation layer PAS may entirely cover two or more emission layers EL and quantum-dot layers QDL.

According to an embodiment, the passivation layer PAS may include one or more of silicon nitride (SiNₓ), silicon oxide (SiOₓ), silicon oxynitride (SiOₓN_{y}), and aluminum oxide (AlOₓ). However, the present disclosure is not limited to the above-described example.

Referring to FIG. 5, according to another embodiment, the light emitting element LE may further include one or more of a superlattice layer SLL, an electron blocking layer EBL, and a distributed Bragg reflective layer DBR.

The superlattice layer SLL may be disposed between the active layer AL and the N-type semiconductor layer SCL1. The superlattice layer SLL may have a structure in which two or more layers having different compositions are alternately stacked. For example, the superlattice layer SLL may have a structure in which a GaN layer and an InGaN layer are alternately disposed. According to an embodiment, the superlattice layer SLL may relieve stress between the N-type semiconductor layer SCL1 and the active layer AL.

The electron blocking layer EBL may be disposed between the active layer AL and the P-type semiconductor layer SCL2. The electron blocking layer EBL may block at least some of the electrons between the active layer AL and the P-type semiconductor layer SCL2 to improve recombination efficiency of the electron-hole pair for light emission. According to an embodiment, the electron blocking layer EBL may include a material having an energy band gap higher than that of the P-type semiconductor layer SCL2 to prevent an overflow of an electron. For example, the electron blocking layer EBL may include AlGaN doped with Mg.

The distributed Bragg reflective layer DBR may be disposed between the P-type semiconductor layer SCL2 and the second electrode ELT2. The distributed Bragg reflection layer DBR may have a structure in which two or more layers having different refractive indices are alternately disposed and may generate Fresnel reflection between the two or more layers. According to an embodiment, a thickness of each layer forming the distributed Bragg reflection layer DBR may be configured so that light incident thereon constructively interferes.

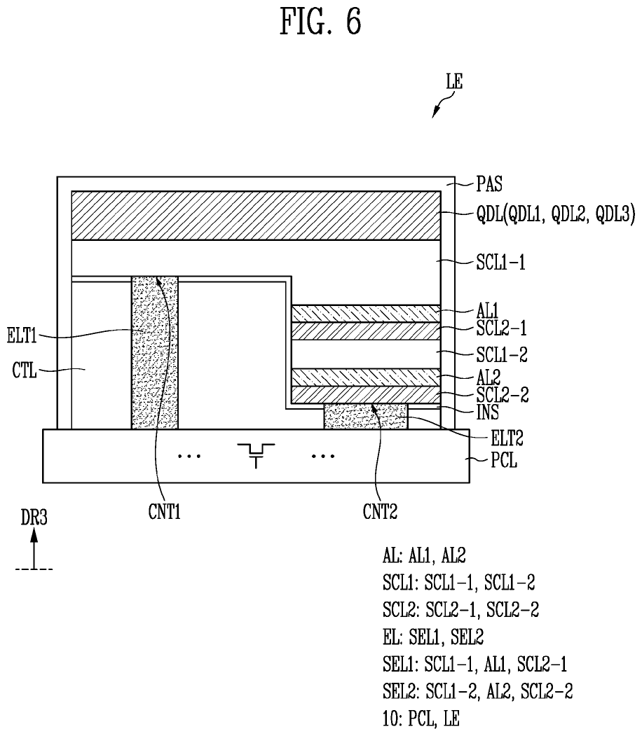

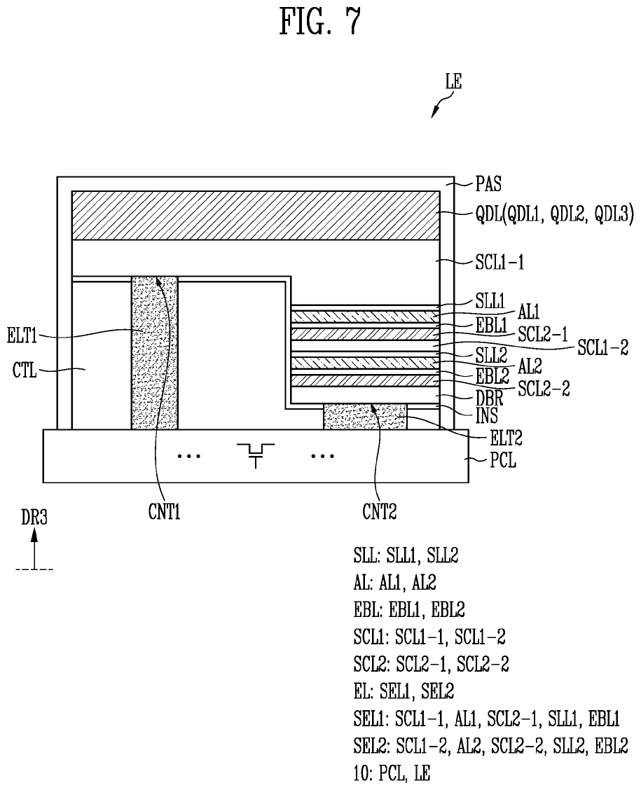

Next, a light emitting element LE according to a second embodiment is described with reference to FIGS. 6 to 8. FIGS. 6 and 7 are schematic cross-sectional views illustrating the light emitting element LE according to the second embodiment. Description that overlaps the above-described content may be only briefly described or may be omitted.

Referring to FIGS. 6 to 8, the light emitting element LE according to the second embodiment is different from the light emitting element LE according to the first embodiment in that the emission layer EL includes a first sub-emission layer SEL1 and a second sub-emission layer SEL2.

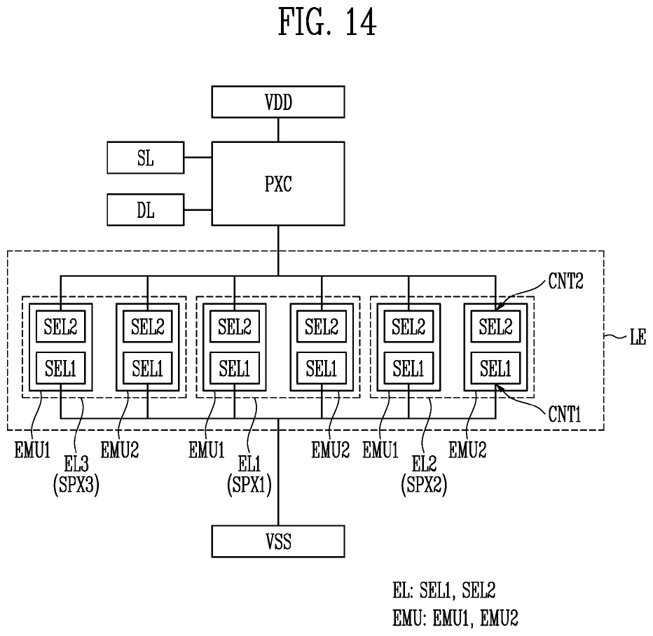

According to an embodiment, the emission layer EL may include a plurality of emission stack structures including two or more active layers AL1 and AL2. For example, the emission layer EL may include a first sub-emission layer SEL1 and a second sub-emission layer SEL2. The first sub-emission layer SEL1 and the second sub-emission layer SEL2 may be connected in series to form a light emitting unit EMU (see, e.g., FIG. 14).

According to an embodiment, the active layer AL may include a first active layer AL1 and a second active layer AL2. The N-type semiconductor layer SCL1 may include a first N-type semiconductor layer SCL1-1 and a second N-type semiconductor layer SCL1-2. The P-type semiconductor layer SCL2 may include a first P-type semiconductor layer SCL2-1 and a second P-type semiconductor layer SCL2-2. The number of sub-emission layers forming the emission layer EL is not particularly limited. According to an embodiment, the emission layer EL may further include an nth sub-emission layer to an mth sub-emission layer (n is a natural number equal to or greater than 3, and m is a natural number equal to or greater than n).

The first sub-emission layer SEL1 may include the first N-type semiconductor layer SCL1-1, a first active layer AL1, and the first P-type semiconductor layer SCL2-1. The second sub-emission layer SEL2 may include the second N-type semiconductor layer SCL1-2, a second active layer AL2, and the second P-type semiconductor layer SCL2-2.

The first sub-emission layer SEL1 and the second sub-emission layer SEL2 may be electrically connected to each other. The first sub-emission layer SEL1 and the second sub-emission layer SEL2 may be electrically connected in series between the first electrode ELT1 and the second electrode ELT2. The first sub-emission layer SEL1 and the second sub-emission layer SEL2 may be electrically connected in series between the first contact portion CNT1 and the second contact portion CNT2.

For example, the first N-type semiconductor layer SCL1-1 may be electrically connected to the first electrode ELT1 and the first active layer AL1. The first active layer AL1 may be electrically connected to the first N-type semiconductor layer SCL1-1 and the first P-type semiconductor layer SCL2-1. The first P-type semiconductor layer SCL2-1 may be electrically connected to the first active layer AL1 and the second N-type semiconductor layer SCL1-2. The second active layer AL2 may be electrically connected to the second N-type semiconductor layer SCL1-2 and the second P-type semiconductor layer SCL2-2. The second P-type semiconductor layer SCL2-2 may be electrically connected to the second active layer AL2 and the second electrode ELT2.

Referring to FIG. 7, according to another embodiment, the light emitting element LE may include a superlattice layer SLL including a first superlattice layer SLL1 and a second superlattice layer SLL2, an electron blocking layer EBL including a first electron blocking layer EBL1 and a second electron blocking layer EBL2, and a distributed Bragg reflection layer DBR. In such an embodiment, the first superlattice layer SLL1 may be disposed between the first N-type semiconductor layer SCL1-1 and the first active layer AL1 and may electrically connect the first N-type semiconductor layer SCL1-1 and the first active layer AL1. The first electron blocking layer EBL1 may be disposed between the first active layer AL1 and the first P-type semiconductor layer SCL2-1 and may electrically connect the first active layer AL1 and the first P-type semiconductor layer SCL2-1. The second superlattice layer SLL2 may be disposed between the second N-type semiconductor layer SCL1-2 and the second active layer AL2 and may electrically connect the second N-type semiconductor layer SCL1-2 and the second active layer AL2. The second electron blocking layer EBL2 may be disposed between the second active layer AL2 and the second P-type semiconductor layer SCL2-2 and may electrically connect the second active layer AL2 and the second P-type semiconductor layer SCL2-2. The distributed Bragg reflective layer DBR may be disposed between the second P-type semiconductor layer SCL2-2 and the second electrode ELT2.

According to an embodiment, the first P-type semiconductor layer SCL2-1 and the second N-type semiconductor layer SCL1-2 maycontact each other.

According to an embodiment, when the emission layer EL includes two or more sub-emission layers SEL1 and SEL2, a risk that the light emitting element LE may be non-emitting is reduced.

For example, the pixel circuit PXC may be electrically connected to the scan line SL and the data line DL and may be electrically connected to a first power source VDD. The pixel circuit PXC may be electrically connected to the light emitting element LE to supply a first signal (e.g., an anode) having a first potential. In addition, a second power source VSS may be electrically connected to the light emitting element LE to supply a second signal (e.g., a cathode) having a second potential (e.g., a potential lower than the first potential). In the illustrated embodiment, the first signal may be provided to the sub-emission layers SEL1 and SEL2 through the second contact portion CNT2, and the second signal may be provided to the sub-emission layers SEL1 and SEL2 through the first contact portion CNT1.

Therefore, an electrical path is normally defined between the first contact portion CNT1 and the second contact portion CNT2 so that the light emitting element LE can normally emit light.

Experimentally, when a short defect occurs in the emission layer EL of the light emitting element LE, formation of one potential difference between the first contact portion CNT1 and the second contact portion CNT2 may be difficult. Thus, light emission of the light emitting element LE may be problematic. However, according to an embodiment, the emission layer EL may include two or more sub-emission layers SEL1 and SEL2 in the electrical path between the first contact portion CNT1 and the second contact portion CNT2. In such an embodiment, even when a short defect occurs in any one of the sub-emission layers SEL1 and SEL2, one or more of the remaining sub-emission layers may normally emit light. Therefore, a risk due to a short defect in the light emitting element LE may be substantially reduced.

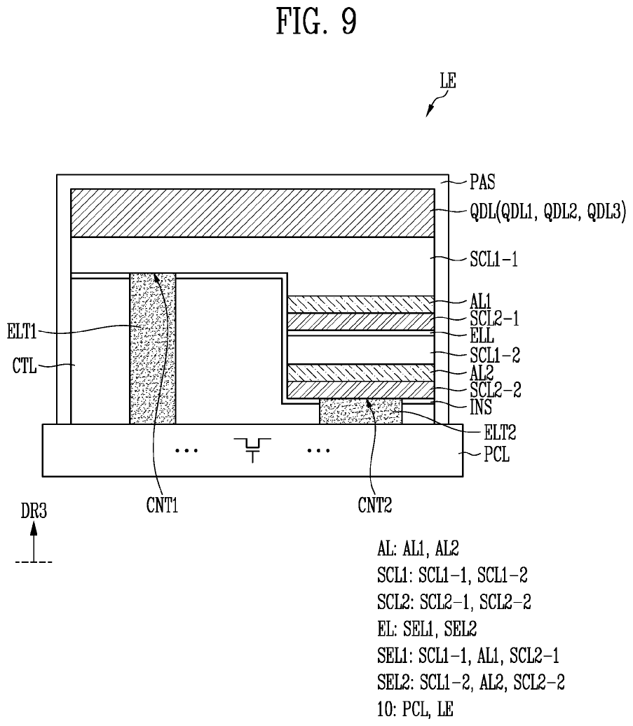

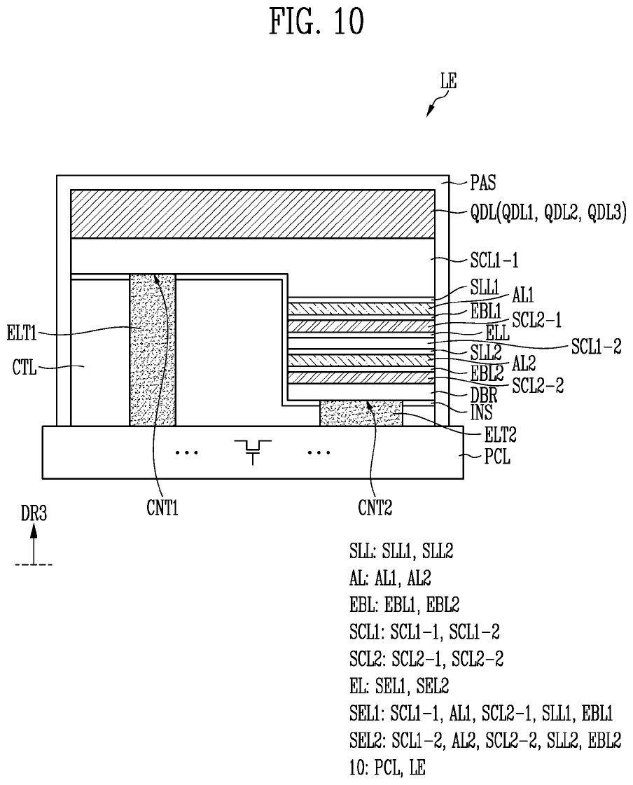

Next, referring to FIGS. 9 and 10, a light emitting element LE according to a third embodiment is described. FIGS. 9 and 10 are schematic cross-sectional views illustrating the light emitting element according to the third embodiment. Content that may overlap the above-described content may be briefly described or may be omitted.

Referring to FIGS. 9 and 10, the light emitting element LE according to the third embodiment is different from the light emitting element LE according to the second embodiment in that the light emitting element LE according to the third embodiment further includes an electrode layer ELL.

The emission layer EL may include the first sub-emission layer SEL1 and the second sub-emission layer SEL2, and according to an embodiment, the emission layer EL may further include the superlattice layer SLL, the electron blocking layer EBL, and the distributed Bragg reflective layer DBR (see, e.g., FIG. 10).

According to an embodiment, the light emitting element LE may further include the electrode layer ELL. The electrode layer ELL may be an adhesive layer for combining (or attaching) the first sub-emission layer SEL1 and the second sub-emission layer SEL2 when the light emitting element LE is manufactured.

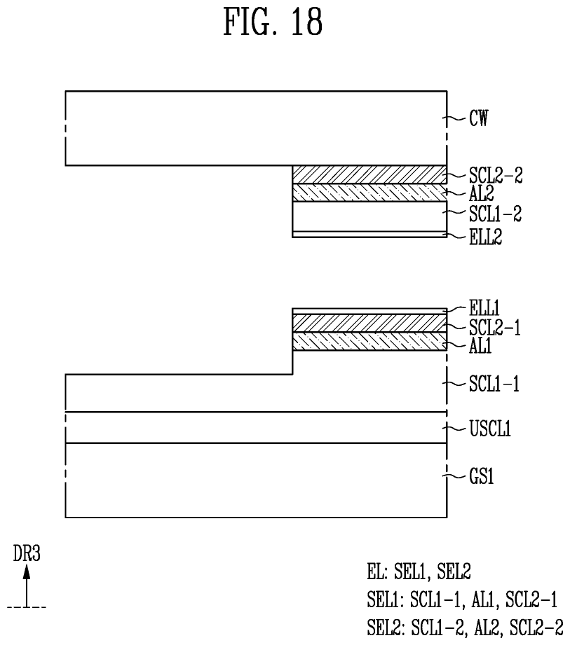

For example, the first sub-emission layer SEL1 and the second sub-emission layer SEL2 may be manufactured in separate processes. In more detail, a first electrode layer ELL1 may be formed on one surface of the first sub-emission layer SEL1, and a second electrode layer ELL2 may be formed on one surface of the second sub-emission layer SEL2 (see, e.g., FIG. 18).

Thereafter, when heat and pressure are applied to the first electrode layer ELL1 and the second electrode layer ELL2, a portion of each of the first electrode layer ELL1 and the second electrode layer ELL2 may be combined (or bonded) to each other to manufacture the electrode layer ELL, and the first sub-emission layer SEL1 and the second sub-emission layer SEL2 may be electrically connected to each other.

According to an embodiment, the electrode layer ELL may include a material for forming a bonding electrode. For example, the electrode layer ELL may include indium tin oxide (ITO). However, the present disclosure is not limited thereto.

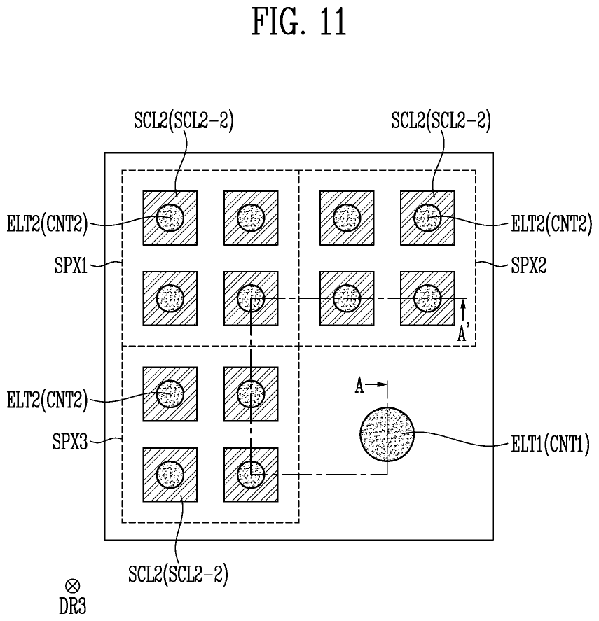

Next, with reference to FIGS. 11 to 14, a parallel connection structure within the sub-pixels SPX1, SPX2, and SPX3 according to an embodiment is described. Content that may overlap the above-described content may be briefly described or may be omitted.

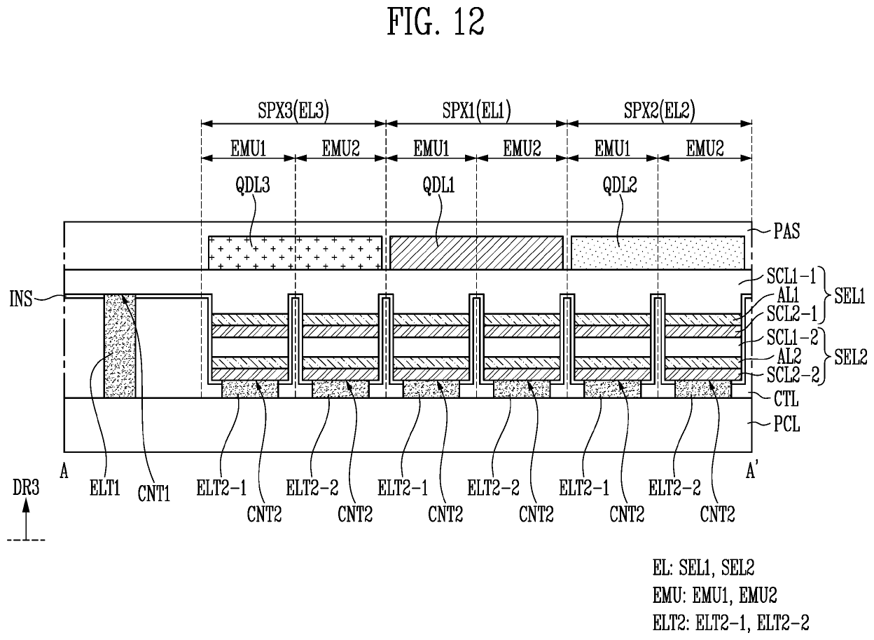

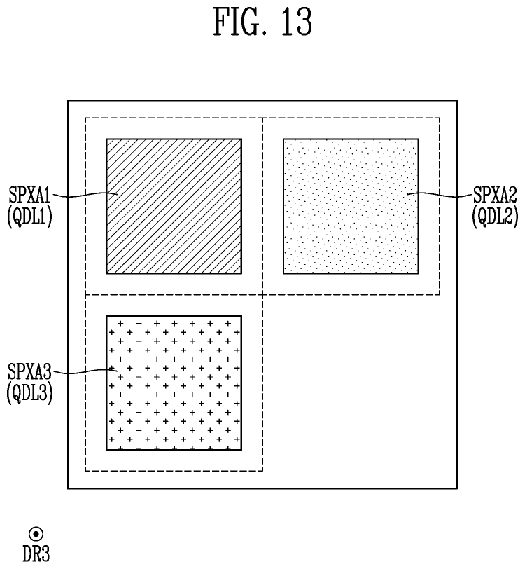

FIGS. 11 and 13 are schematic plan views illustrating a display device according to an embodiment. FIG. 11 shows the sub-pixels SPX and a configuration for forming the sub-pixels SPX1, SPX2, and SPX3 according to an embodiment when viewed from a rear surface of the display device 10. FIG. 13 shows the sub-pixels SPX and another configuration for forming the sub-pixels SPX1, SPX2, and SPX3 according to an embodiment when viewed from an upper surface of the display device 10. FIG. 12 is a schematic cross-sectional view taken along the line A-A′ of FIG. 11. FIG. 12 shows the sub-pixels SPX1, SPX2, and SPX3 according to an embodiment. FIG. 14 is a schematic diagram illustrating a parallel connection structure of emission layers according to an embodiment.

Referring to FIGS. 11 to 14, the first to third sub-pixels SPX1, SPX2, and SPX3 may be arranged according to various arrangement structures or configurations. For example, the first to third sub-pixel areas SPXA1, SPXA2, and SPXA3 may be adjacent to each other. However, an arrangement structure of the first to third sub-pixels SPX1, SPX2, and SPX3 is not particularly limited.

The first to third sub-pixel areas SPXA1, SPXA2, and SPXA3 may correspond to the first to third quantum-dot layers QDL1, QDL2, and QDL3, respectively. For example, the first sub-pixel area SPXA1 may overlap the first quantum-dot layer QDL1 in a plan view. The second sub-pixel area SPXA2 may overlap the second quantum-dot layer QDL2 in a plan view. The third sub-pixel area SPXA3 may overlap the third quantum-dot layer QDL3 in a plan view.

According to an embodiment, one anode signal may be supplied to the light emitting elements LE of each of the first to third sub pixels SPX1, SPX2, and SPX3 so that the first to third sub-pixels SPX1, SPX2, and SPX3 emit light of different colors.

According to an embodiment, the N-type semiconductor layer SCL1 (e.g., the first N-type semiconductor layer SCL1-1) of each of the first to third emission layers EL1, EL2, and EL3 may be electrically connected to the first electrode ELT1 in common through the first contact portion CNT1.

According to an embodiment, each of the sub-pixels SPX1, SPX2, and SPX3 may include two or more light emitting units EMU. For example, the two or more light emitting units EMU may include a first light emitting unit EMU1 and a second light emitting unit EMU2. The number of light emitting units EMU, however, is not particularly limited.

Each light emitting unit EMU may include one or more sub-emission layers SEL1 and SEL2. For example, each of the first light emitting unit EMU1 and the second light emitting unit EMU2 may include the first sub-emission layer SEL1 and the second sub-emission layer SEL2.

According to an embodiment, the emission layers EL forming each of the light emitting units EMU may share the N-type semiconductor layer SCL1 (e.g., the first N-type semiconductor layer SCL1-1) with each other.

The light emitting units EMU may be electrically connected in parallel between the first power source VDD and the second power source VSS. For example, the first emission layer EL1 for forming the first sub-pixel SPX1 may include light emitting units EMU forming different electrical paths from each other. The second emission layer EL2 for forming the second sub-pixel SPX2 may include light emitting units EMU forming different electrical paths from each other. The third emission layer EL3 for forming the third sub-pixel SPX3 may include light emitting units EMU forming different electrical paths from each other.

For example, each light emitting unit EMU may be electrically connected to the second electrode ELT2. For example, the second electrode ELT2 may include a (2-1)th electrode ELT2-1 and a (2-2)th electrode ELT2-2. The first light emitting unit EMU1 may correspond to the (2-1)th electrode ELT2-1. The second light emitting unit EMU2 may correspond to the (2-2)th electrode ELT2-2. The first light emitting unit EMU1 may be electrically connected to the (2-1)th electrode ELT2-1. The second light emitting unit EMU2 may be electrically connected to the (2-2)th electrode ELT2-2. According to an embodiment, the number of second electrodes ELT2 spaced apart from each other in each of the sub-pixels SPX1, SPX2, and SPX3 is not particularly limited and may be provided in the same number corresponding to the light emitting units EMU.

The (2-1)th electrode ELT2-1 and the (2-2)th electrode ELT2-2 may be spaced apart from each other. The (2-1)th electrode ELT2-1 and the (2-2)th electrode ELT2-2 may be electrically connected to a line in the pixel circuit layer PCL through different contact holes (e.g., contact openings) in the pixel circuit layer PCL. For example, the (2-1)th electrode ELT2-1 may be electrically connected to the line in the pixel circuit layer PCL through a first contact hole (e.g., a first contact opening), and the (2-2)th electrode ELT2-2 may be electrically connected to the line in the pixel circuit layer PCL through a second contact hole (e.g., a second contact opening).

According to an embodiment, because an electrical path may be defined in each of the light emitting units EMU, two or more second contact portions CNT2 may be formed in each of the sub-pixels SPX1, SPX2, and SPX3.

According to an embodiment, the light emitting units EMU may be electrically connected in parallel within the same sub-pixel (e.g., within any one of the first to third sub-pixels SPX1, SPX2, and SPX3). Accordingly, a risk of the light emitting element LE malfunctioning or being defective may be reduced. For example, to normally supply the anode signal from the pixel circuit PXC, the line forming the pixel circuit PXC and the second electrode ELT2 are normally connected to each other. The second electrode ELT2 and the line forming the pixel circuit PXC may be electrically connected to each other through a contact member passing through an upper insulating layer (e.g., the protective layer and/or the via layer) of the pixel circuit PXC. According to an embodiment, the light emitting units EMU may be electrically connected in parallel within the same sub-pixel (e.g., within any one of the first to third sub-pixels SPX1, SPX2, and SPX3), such that even when a contact member for any one of the light emitting units EMU is formed abnormally and normal operation is difficult, any one or more of the other light emitting units EMU may operate normally. Accordingly, a risk of an abnormal operation of the emission layers EL for each of the sub-pixels SPX1, SPX2, and SPX3 may be reduced.

In addition, according to an embodiment, because the first sub-emission layer SEL1 and the second sub-emission layer SEL2 are formed in each of the light emitting units EMU, a risk of light emission due to a short defect may be resolved in each of the light emitting units EMU. Because each of the light emitting units EMU may be electrically connected in parallel within one sub-pixel SPX1, SPX2, and SPX3, a risk of light emission due to a defect during a processing step (e.g., a process of forming the second electrode ELT2 or a contact member for electrically connecting the second electrode ELT2 and the pixel circuit PXC) may be reduced. Therefore, according to an embodiment, various risks to the light emitting element LE may be reduced or resolved, and thus, the display device 10 may have improved light emission reliability.

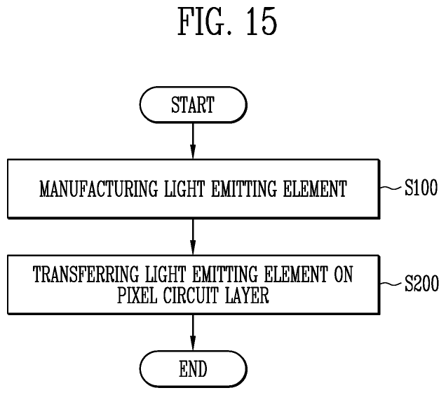

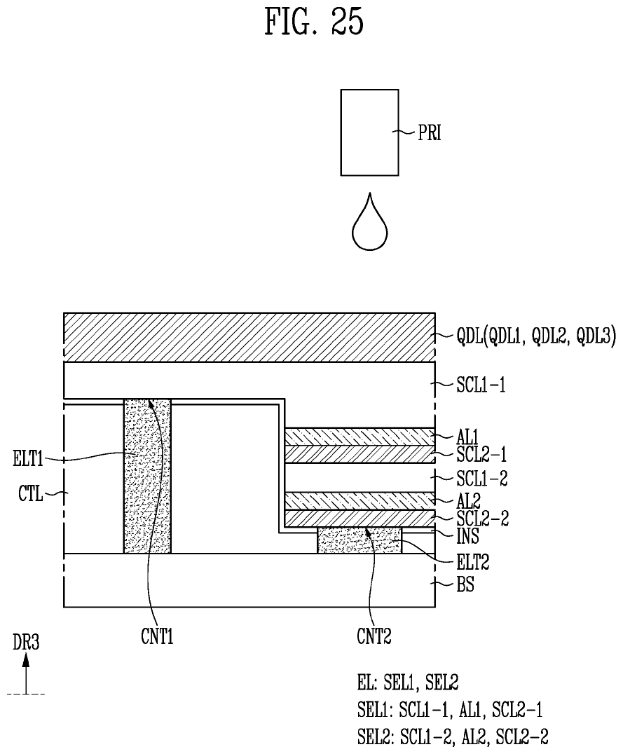

Hereinafter, a method of manufacturing the display device 10 according to an embodiment is described with reference to FIGS. 15 to 25. Content that may overlap the above-described content may be briefly described or may be omitted.

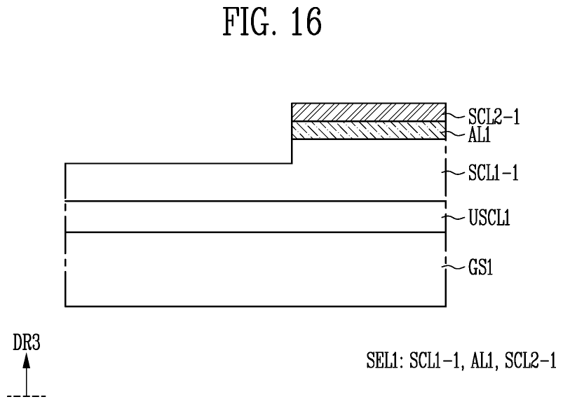

FIG. 15 is a schematic flowchart describing a method of manufacturing a display device according to an embodiment. FIGS. 16 to 25 are schematic cross-sectional views for each process step of a method of manufacturing a display device according to an embodiment.

According to an embodiment, the method of manufacturing the display device 10 may include manufacturing the light emitting element (S100) and transferring the light emitting element on (or onto) the pixel circuit layer (S200).

First, the method of manufacturing the display device 10 according to an embodiment is described with reference to FIGS. 15 to 21.

FIGS. 15 to 21 show an embodiment in which the first sub-emission layer SEL1 and the second sub-emission layer SEL2 are combined by using the first electrode layer ELL1 and the second electrode layer ELL2. For example, FIGS. 15 to 21 may illustrate a method of manufacturing the light emitting element LE according to the embodiment described above with reference to FIGS. 9 and 10.

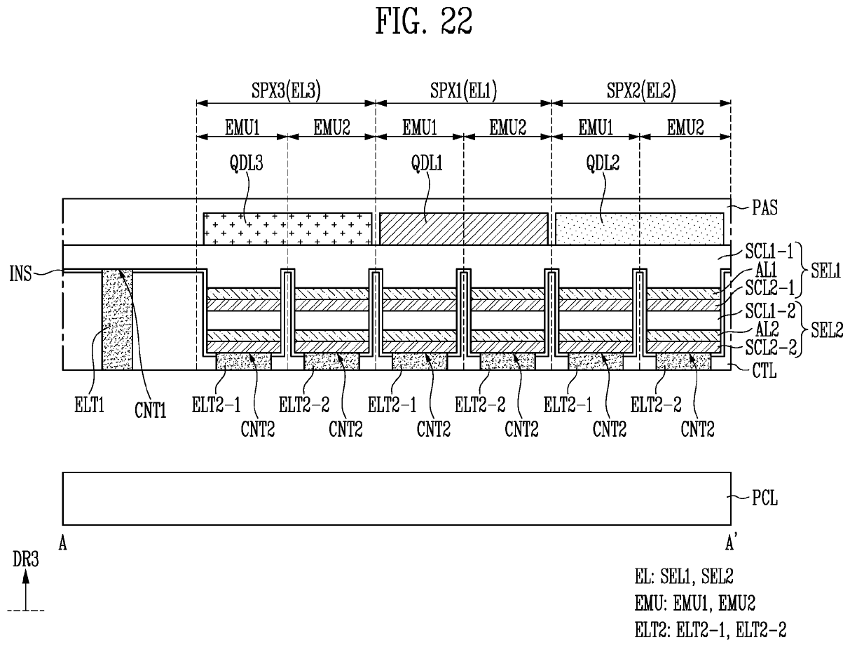

Referring to FIG. 15, the method of manufacturing the display device 10 according to an embodiment may include manufacturing the light emitting element (S100) and transferring the light emitting element on the pixel circuit layer (S200). FIGS. 16 to 21 show steps of manufacturing the light emitting element (S100), and FIG. 22 shows a step of transferring the light emitting element on the pixel circuit layer (S200).

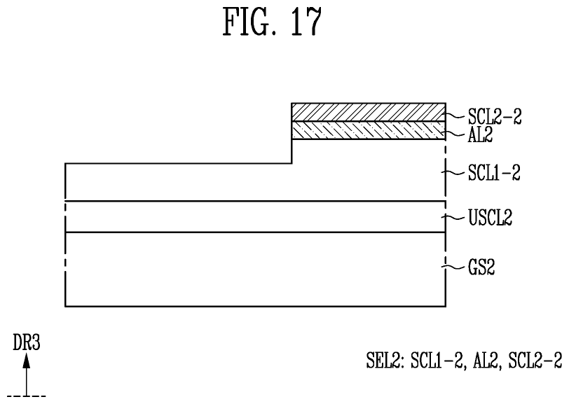

Referring to FIGS. 16 and 17, each of the first sub-emission layer SEL1 and the second sub-emission layer SEL2 may be manufactured. For example, a first undoped semiconductor layer USCL1, the first N-type semiconductor layer SCL1-1, the first active layer AL1, and the first P-type semiconductor layer SCL2-1 may be patterned on a first growth substrate GS1. A second undoped semiconductor layer USCL2, the second N-type semiconductor layer SCL1-2, the second active layer AL2, and the second P-type semiconductor layer SCL2-2 may be patterned on a second growth substrate GS2.

The first growth substrate GS1 and the second growth substrate GS2 may be a base plate for growing a target material. For example, the first growth substrate GS1 and the second growth substrate GS2 may be a wafer for epitaxial growth for one material. The first growth substrate GS1 and the second growth substrate GS2 may be a GaAs, GaP, or InP substrate, but a material for forming the first growth substrate GS1 and the second growth substrate GS2 is not limited.

The first undoped semiconductor layer USCL1 and the second undoped semiconductor layer USCL2 may be disposed on the first growth substrate GS1 and the second growth substrate GS2, respectively, to reduce a defect of semiconductor layers formed on the first growth substrate GS1 and the second growth substrate GS2. According to an embodiment, the first undoped semiconductor layer USCL1 and the second undoped semiconductor layer USCL2 may include GaN without a separate dopant (e.g., undoped GaN), but a material for forming the first undoped semiconductor layer USCL1 and the second undoped semiconductor layer USCL2 is not limited. According to an embodiment, the first undoped semiconductor layer USCL1 and the second undoped semiconductor layer USCL2 may be formed by using a metal-organic chemical vapor deposition (MOCVD) method.

The first N-type semiconductor layer SCL1-1, the first active layer AL1, and the first P-type semiconductor layer SCL2-1 may be sequentially grown on the first undoped semiconductor layer USCL1. A method of growing the first N-type semiconductor layer SCL1-1, the first active layer AL1, and the first P-type semiconductor layer SCL2-1 is not particularly limited. Layers for forming each of the first N-type semiconductor layer SCL1-1, the first active layer AL1, and the first P-type semiconductor layer SCL2-1 may be grown on the first undoped semiconductor layer USCL1, and the first sub-emission layer SEL1 patterned according to one structure may be manufactured by etching the layers.

The second N-type semiconductor layer SCL1-2, the second active layer AL2, and the second P-type semiconductor layer SCL2-2 may be sequentially grown on the second undoped semiconductor layer USCL2. A method of growing the second N-type semiconductor layer SCL1-2, the second active layer AL2, and the second P-type semiconductor layer SCL2-2 is not particularly limited. Layers for forming the second N-type semiconductor layer SCL1-2, the second active layer AL2, and the second P-type semiconductor layer SCL2-2 may be grown on the second undoped semiconductor layer USCL2, and the second sub-emission layer SEL2 patterned according to one structure may be manufactured by etching the layers.

According to an embodiment, the electron blocking layer EBL and/or the superlattice layer SLL may be patterned between some layers.

According to an embodiment, the first sub-emission layer SEL1 and the second sub-emission layer SEL2 may form the light emitting unit EMU.

Referring to FIG. 18, the electrode layers ELL1 and ELL2 for bonding the first sub-emission layer SEL1 and the second sub-emission layer SEL2 on the first sub-emission layer SEL1 and the second sub-emission layer SEL2 may be formed, and the first sub-emission layer SEL1 and the second sub-emission layer SEL2 may be bonded to each other.

In this step, the first electrode layer ELL1 may be disposed on the first sub-emission layer SEL1. For example, the first electrode layer ELL1 may be patterned on the first P-type semiconductor layer SCL2-1. According to an embodiment, the first electrode layer ELL1 may include ITO.

At this step, the second electrode layer ELL2 may be disposed on the second sub-emission layer SEL2. For example, the second electrode layer ELL2 may be patterned on the second N-type semiconductor layer SCL1-2. According to an embodiment, the second electrode layer ELL2 may include ITO.

At this step, the second sub-emission layer SEL2 may be connected to (or attached to) a carrier wafer CW, and then, the second sub-emission layer SEL2 may be moved adjacent to the first sub-emission layer SEL1 so that the first electrode layer ELL1 and the second electrode layer ELL2 contact each other. In addition, by applying heat and pressure to the first electrode layer ELL1 and the second electrode layer ELL2, the first electrode layer ELL1 and the second electrode layer ELL2 may be bonded to each other, and the electrode layer ELL in which the first electrode layer ELL1 and the second electrode layer ELL2 are combined with each other may be formed.

According to an embodiment, the carrier wafer CW may be temporarily bonded to the second sub-emission layer SEL2 proceeding a subsequent process and may be debonded therefrom after the subsequent process.

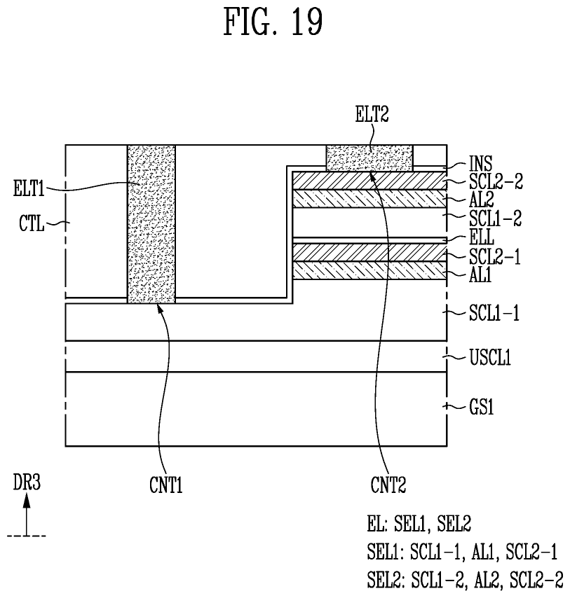

Referring to FIG. 19, the insulating layer INS may be patterned on the first sub-emission layer SEL1 and the second sub-emission layer SEL2, the intermediate layer CTL may be formed on the insulating layer INS, and the first electrode ELT1 and the second electrode ELT2 may be patterned.

At this step, after the insulating layer INS is deposited by various suitable methods, the insulating layer INS may be etched (e.g., by dry etching) in a partial area for forming the first electrode ELT1 and the second electrode ELT2. According to an embodiment, the insulating layer INS may be formed by using a chemical vapor deposition (CVD) method or an atomic layer deposition (ALD) method. However, the present disclosure is not limited thereto.

At this step, the insulating layer INS may expose a portion of the emission layer EL for forming the first contact portion CNT1 and the second contact portion CNT2.

At this step, the first electrode ELT1 and the first N-type semiconductor layer SCL1-1 may be electrically connected by forming (or at) the first contact portion CNT1. The second electrode ELT2 and the second P-type semiconductor layer SCL2-2 may be electrically connected by forming (or at) the second contact portion CNT2.

At this step, a plurality of second electrodes ELT2 may be formed. For example, a separate second electrode ELT2 may be formed adjacent to the emission layers EL corresponding to each of the sub-pixels SPX1, SPX2, and SPX3. For example, as described above, the second electrode ELT2 may be manufactured to include the (2-1)th electrode ELT2-1 and the (2-2)th electrode ELT2-2, which are separated from each other.

At this step, the first sub-emission layer SEL1 and the second sub-emission layer SEL2 may be provided to be electrically connected between the first electrode ELT1 and the second electrode ELT2.

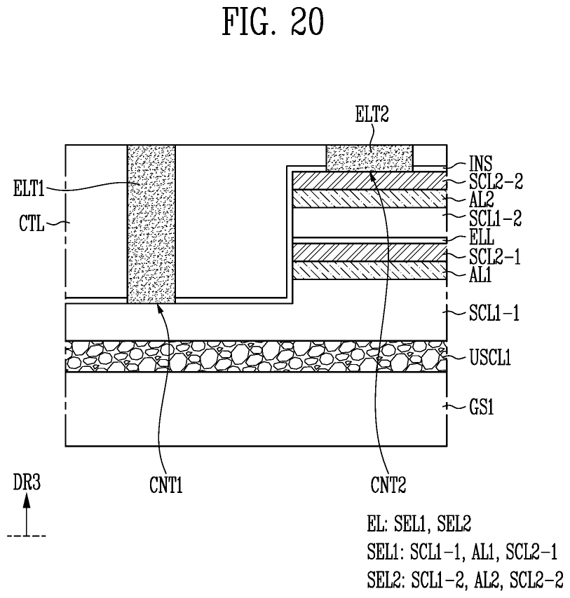

Referring to FIG. 20, an electro-chemical (EC) etching process may be performed on the undoped semiconductor layer (e.g., the first undoped semiconductor layer USCL1), and a porous layer having a porous structure may be formed (e.g., may be formed in its place).

According to an embodiment, an oxalic acid solution may be used to perform the electrochemical etching process, but the present disclosure is not limited thereto. The electrochemical etching process may be performed, and thus, the porous layer having a porous structure in which a quantum-dot material may be provided may be formed from the first undoped semiconductor layer USCL1.

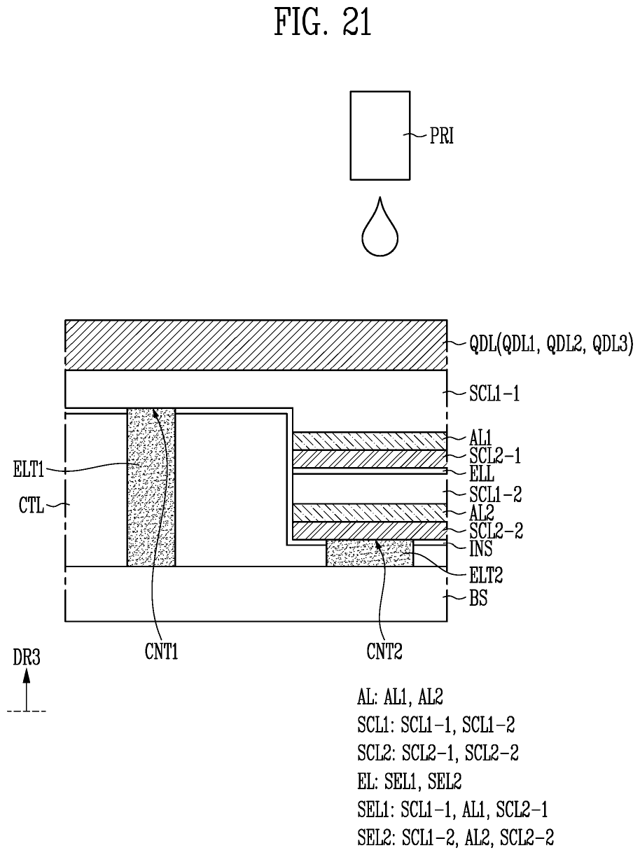

Thereafter, the growth substrate (e.g., the first growth substrate GS1) may be removed, and a structure including the emission layer EL may be moved onto the base BS for performing an inkjet-printing process (see, e.g., FIG. 21). For example, the growth substrate may be removed by a laser lift-off method.

Referring to FIG. 21, the quantum-dot layer QDL may be formed by performing an inkjet-printing process.

For example, a printing device PRI may provide an ink including a material for forming the quantum-dot layer QDL to the porous layer. The printing device PRI may be a fluidic printer configured to pressure eject a droplet.

At this step, the first quantum-dot layer QDL1 may be formed in an area for forming the first sub-pixel SPX1. The second quantum-dot layer QDL2 may be formed in an area for forming the second sub-pixel SPX2. The third quantum-dot layer QDL3 may be formed in an area for forming the third sub-pixel SPX3.

The passivation layer PAS covering the emission layer EL and the quantum dot layer QDL may be formed to protect the emission layer EL and the quantum dot layer QDL. According to an embodiment, the passivation layer PAS may be deposited by using an atomic layer deposition (ALD) method, but the present disclosure is not limited thereto.

Referring to FIG. 22, the light emitting element LE may be transferred on the pixel circuit layer PCL.

According to an embodiment, the light emitting element LE may be transferred by various methods. For example, a device using one or more of a transfer method using a stamp, a transfer method using a laser, a transfer method using electrostatic force, a transfer method using magnetic force and electromagnetic force, and a transfer method using an adhesive may be used. However, the present disclosure is not limited to a specific example.

As described above, because two or more sub-emission layers SEL1 and SEL2 may be included in a single light emitting unit EMU, a risk of an abnormal operation of the light emitting unit EMU (or the emission layer EL) may be reduced. In addition, because two or more second contact portions CNT2 may be formed, and thus, each of the light emitting units EMU may be electrically connected in parallel within one sub-pixel SPX1, SPX2, and SPX3, a risk of an abnormal operation of the sub pixels SPX1, SPX2, and SPX3 may be reduced.

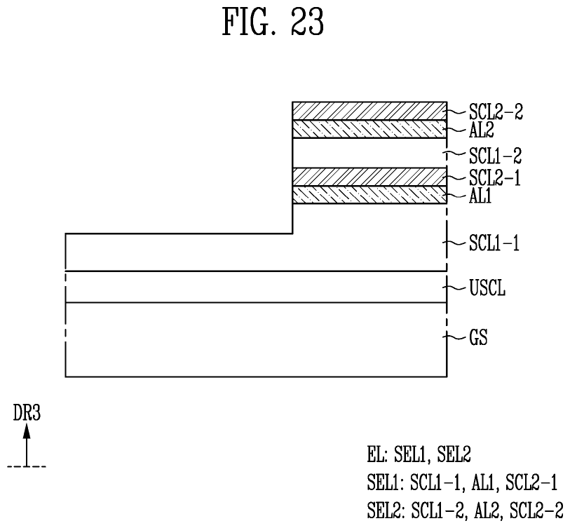

Next, a method of manufacturing the display device 10 according to another embodiment is described with reference to FIGS. 23 to 25. Content that may overlap the above-described content may be briefly described or may be omitted.

FIGS. 23 to 25 show an embodiment in which the first sub-emission layer SEL1 and the second sub-emission layer SEL2 are sequentially formed. For example, FIGS. 23 to 25 may illustrate a method of manufacturing the light emitting element LE according to the embodiment described above with reference to FIGS. 6 and 7.

Referring to FIG. 23, the first sub-emission layer SEL1 and the second sub-emission layer SEL2 may be sequentially formed on the same growth substrate GS. The first sub-emission layer SEL1 and the second sub-emission layer SEL2 may be patterned on the growth substrate GS and the undoped semiconductor layer USCL. In such an embodiment, after sequentially growing semiconductor layers for forming the first sub-emission layer SEL1 and the second sub-emission layer SEL2, the grown layers may be etched to manufacture the first sub-emission layer SEL1 and the second sub-emission layer SEL2.

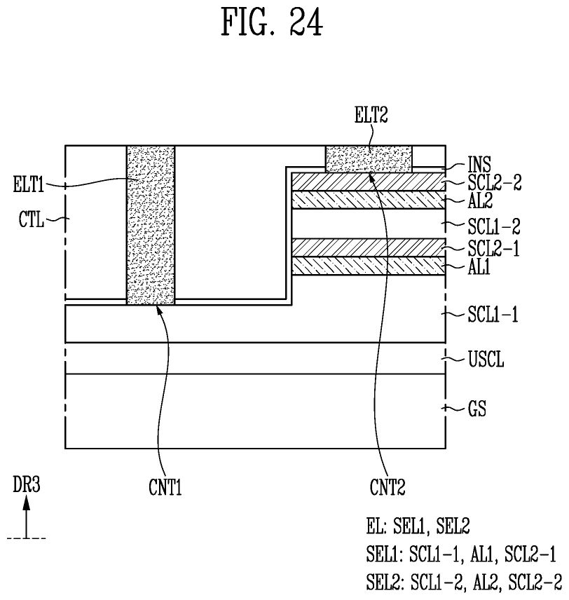

Thereafter, the insulating layer INS, the first electrode ELT1, the second electrode ELT2, and the intermediate layer CTL may be formed (see, e.g., FIG. 24). In addition, after performing an electrochemical etching process on the undoped semiconductor layer USCL, an inkjet printing process may be performed to form the quantum-dot layer QDL. In addition, the light emitting element LE according to an embodiment may be manufactured by forming the passivation layer PAS. Thereafter, the display device 10 according to an embodiment may be manufactured by transferring the light emitting element LE manufactured according to the illustrated embodiment on the pixel circuit layer PCL as, for example, described above with respect to FIG. 22.

Although the present disclosure has been described with reference to embodiments, those having ordinary skill in the art will understand that the present disclosure may be variously modified and changed without departing from the spirit and technical idea of the present disclosure as described in the claims and their equivalents.

Therefore, the scope of the present disclosure should not be limited to the content described in the detailed description of the specification but is defined by the claims and their equivalents.

What is claimed is:

1. A display device comprising:
a pixel circuit layer comprising a base layer and a pixel circuit on the base layer; and
a light emitting element on the pixel circuit layer,
wherein the light emitting element comprises:
a first electrode;
a second electrode; and
an emission layer electrically connected to the first electrode through a first contact portion and electrically connected to the second electrode through a second contact portion,
wherein the emission layer comprises:
a first sub-emission layer comprising a first N-type semiconductor layer, a first P-type semiconductor layer, and a first active layer between the first N-type semiconductor layer and the first P-type semiconductor layer; and
a second sub-emission layer comprising a second N-type semiconductor layer, a second P-type semiconductor layer, and a second active layer between the second N-type semiconductor layer and the second P-type semiconductor layer, and
wherein the first sub-emission layer and the second sub-emission layer are electrically connected in series between the first electrode and the second electrode.

2. The display device according to claim 1, wherein the pixel circuit layer comprises a first power source and a second power source,
wherein the first power source is electrically connected to the pixel circuit layer, and
wherein the first sub-emission layer and the second sub-emission layer are electrically connected between the pixel circuit layer and the second power source.

3. The display device according to claim 1, wherein the emission layer further comprises a distributed Bragg reflective layer on the second P-type semiconductor layer,
wherein the first sub-emission layer further comprises a first superlattice layer between the first N-type semiconductor layer and the first active layer and a first electron blocking layer between the first active layer and the first P-type semiconductor layer, and
wherein the second sub-emission layer further comprises a second superlattice layer between the second N-type semiconductor layer and the second active layer and a second electron blocking layer between the second active layer and the second P-type semiconductor layer.

4. The display device according to claim 1, wherein the emission layer further comprises an electrode layer between the first P-type semiconductor layer and the second N-type semiconductor layer.

5. The display device according to claim 1, wherein the first P-type semiconductor layer and the second N-type semiconductor layer contact each other.

6. The display device according to claim 1, further comprising a quantum-dot layer on the emission layer,
wherein light emitted by the emission layer passes through the quantum-dot layer.

7. The display device according to claim 6, further comprising:
a first sub-pixel area from which light of a first color is emitted;
a second sub-pixel area from which light of a second color is emitted; and
a third sub-pixel area from which light of a third color is emitted,
wherein the emission layer comprises a first emission layer overlapping the first sub-pixel area, a second emission layer overlapping the second sub-pixel area, and a third emission layer overlapping the third sub-pixel area in a plan view.

8. The display device according to claim 7, wherein the first sub-emission layer and the second sub-emission layer form a light emitting unit,
wherein the light emitting unit comprises a first light emitting unit and a second light emitting unit, and
wherein the first light emitting unit and the second light emitting unit are in each of the first sub-pixel area, the second sub-pixel area, and the third sub-pixel area.

9. The display device according to claim 8, wherein the second electrode comprises a (2-1)th electrode corresponding to the first light emitting unit and a (2-2)th electrode corresponding to the second light emitting unit.

10. The display device according to claim 9, wherein the pixel circuit layer comprises a first power source and a second power source, and
wherein the first light emitting unit and the second light emitting unit are electrically connected in parallel between the first power source and the second power source.

11. The display device according to claim 9, wherein the second contact portion comprises a plurality of contact portions in each of the first sub-pixel area, the second sub-pixel area, and the third sub-pixel area.

12. A display device comprising sub-pixels, the display device comprising:
a pixel circuit layer comprising a base layer and a pixel circuit on the base layer; and
a light emitting element on the pixel circuit layer,
wherein the light emitting element comprises:
a first electrode;
a second electrode;
an emission layer electrically connected to the first electrode through a first contact portion and electrically connected to the second electrode through a second contact portion; and
a quantum-dot layer on the emission layer,
wherein each of the sub-pixels has a sub-pixel area overlapping the quantum-dot layer in a plan view, and
wherein the second contact portion comprises contact portions in the sub-pixel area of each of the sub-pixels.

13. A method of manufacturing a display device, the method comprising:
manufacturing a light emitting element; and
transferring the light emitting element onto a pixel circuit layer,
wherein the manufacturing of the light emitting element comprises:
manufacturing a first sub-emission layer comprising a first N-type semiconductor layer, a first P-type semiconductor layer, and a first active layer between the first N-type semiconductor layer and the first P-type semiconductor layer;
manufacturing a second sub-emission layer comprising a second N-type semiconductor layer, a second P-type semiconductor layer, and a second active layer between the second N-type semiconductor layer and the second P-type semiconductor layer; and
forming a first electrode electrically connected to the first N-type semiconductor layer at a first contact portion and a second electrode electrically connected to the second P-type semiconductor layer at a second contact portion, and
wherein the first sub-emission layer and the second sub-emission layer are electrically connected in series between the first electrode and the second electrode.

14. The method according to claim 13, wherein the manufacturing of the light emitting element further comprises:
forming a first electrode layer on the first sub-emission layer;
forming a second electrode layer on the second sub-emission layer; and
bonding the first electrode layer and the second electrode layer.

15. The method according to claim 13, wherein the first sub-emission layer and the second sub-emission layer are sequentially formed on a growth substrate.

16. The method according to claim 13, wherein the manufacturing of the first sub-emission layer comprises forming an undoped semiconductor layer on a growth substrate, and
wherein the method further comprises:
forming a porous structure by performing an electrochemical etching process on the undoped semiconductor layer; and
forming a quantum-dot layer by performing an inkjet printing process of providing an ink comprising a quantum-dot to the porous structure.

17. The method according to claim 16, further comprising forming a passivation layer covering the quantum-dot layer and the first sub-emission layer.

18. The method according to claim 13, wherein the display device comprises a plurality of sub-pixels,
wherein the second electrode comprises a (2-1)th electrode and a (2-2)th electrode, and
wherein the (2-1)th electrode and the (2-2)th electrode are in each of the plurality of sub-pixels.

19. The method according to claim 13, wherein the manufacturing of the first sub-emission layer comprises:
forming a superlattice layer between the first N-type semiconductor layer and the first active layer; and
forming an electron blocking layer between the first active layer and the first P-type semiconductor layer.

20. A method of manufacturing a display device, the method comprising:
manufacturing a light emitting element; and
transferring the light emitting element onto a pixel circuit layer,
wherein the manufacturing of the light emitting element comprises:
manufacturing an emission layer;
forming a first electrode electrically connected to a first contact portion of the emission layer and a second electrode electrically connected to a second contact portion of the emission layer; and
forming a quantum-dot layer on the emission layer,
wherein the manufacturing of the emission layer comprises disposing an undoped semiconductor layer, an N-type semiconductor layer, an active layer, and a P-type semiconductor layer on a growth substrate,
wherein the emission layer forms a first light emitting unit and a second light emitting unit, and
wherein the forming of the second electrode comprises forming a (2-1)th electrode corresponding to the first light emitting unit and a (2-2)th electrode corresponding to the second light emitting unit.
